(19) United States
(12) Patent Application Publication
(10) Pub. No.: US 2015/0243439 A1
(43) Pub. Date: Aug. 27, 2015

(54) MULTILAYER CERAMIC ELECTRONIC COMPONENT AND BOARD HAVING THE SAME MOUNTED THEREON

(71) Applicant: SAMSUNG ELECTRO-MECHANICS CO., LTD., Suwon-Si (KR)

(72) Inventor: Joon Hwan KWAG, Suwon-Si (KR)

(21) Appl. No.: 14/307,157

(22) Filed: Jun. 17, 2014

(30) Foreign Application Priority Data
Feb. 26, 2014 (KR) 10-2014-0022677

(51) Int. Cl. H01G 4/228; H05K 1/18; H01G 4/008; H01G 4/30; H01G 4/012

(52) U.S. Cl. CPC H01G 4/228; H01G 4/30; H01G 4/012; H01G 4/008; H05K 1/181

(57) ABSTRACT

A multilayer ceramic electronic component may include: a ceramic body including dielectric layers; an active layer configured to form capacitance by stacking internal electrodes alternately exposed to end surfaces of the ceramic body with the dielectric layers interposed therebetween; upper and lower cover layers formed on and below the active layer; and first and second external electrodes formed on end portions of the ceramic body. In a cross-section of the ceramic body in length-thickness direction, the external electrodes may include conductive layers formed at corner portions of the ceramic body, base electrodes covering the conductive layers, and terminal electrodes formed on the base electrodes, the conductive layers being positioned outside the active layer of the ceramic body.

### CROSS-REFERENCE TO RELATED APPLICATION

This application claims the benefit of Korean Patent Application No. 10-2014-0022677 filed on Feb. 26, 2014, with the Korean Intellectual Property Office, the disclosure of which is incorporated herein by reference.

### BACKGROUND

The present disclosure relates to a multilayer ceramic electronic component capable of improving corner coverage of external electrodes to thereby improve reliability, and a board having the same mounted thereon.

In accordance with the recent trend for the miniaturization of electronic products, the demand for a multilayer ceramic electronic component having a small size and high capacitance has also increased.

In accordance with the demand for multilayer ceramic electronic components having a small size and high capacitance, external electrodes of the multilayer ceramic electronic component have also been thinned.

In order to form external electrodes according to the related art, in general, copper (Cu) is used as a conductive metal, and an external electrode paste is prepared by mixing glass and a base resin, an organic solvent, and the like, with such copper, and the external electrode paste is then applied to both end surfaces of a ceramic body. Thereafter, the metal in the external electrodes is sintered at the time of sintering the ceramic body.

The external electrode paste contains a conductive metal such as copper (Cu) as a main material thereof to thereby ensure chip sealing properties and electrical connectivity between the external electrodes and a chip, and contains glass as an auxiliary material thereof to thereby provide adhesive strength between the external electrodes and the chip, simultaneously with filling voids during sintering shrinkage of the metal.

However, as the multilayer ceramic electronic component is miniaturized and is designed to have high capacitance, a design for securing such a high level of capacitance by increasing the number of stacked internal electrodes and decreasing thicknesses of upper and lower cover layers has been generally applied.

Therefore, the internal electrodes are formed up to the vicinity of corner portions of the ceramic body at which thicknesses of the external electrodes are decreased at the time of forming the external electrodes, such that the internal electrodes may be easily exposed to physical or chemical impacts.

Particularly, as the overall thicknesses of the external electrodes of the multilayer ceramic electronic component are decreased, the thicknesses of the external electrodes in the vicinity of the corner portions of the ceramic body are further decreased, whereby corner coverage may deteriorate and a plating solution may infiltrate thereinto.

Further, in the case of external electrodes used in a high capacitance electronic component, in order to decrease thermal impact at the time of sintering the external electrodes, a material capable of being sintered at a relatively low temperature is used. Particularly, in the case of glass softened at low temperatures, it may have relatively weak acid resistance at the time of plating. Due to these features, in the case in which a plating layer is formed in outer portions of the external electrodes, a plating solution may easily infiltrate into the chip body, a leading cause of deteriorations in product quality due to deteriorations in moisture resistance reliability.

### RELATED ART DOCUMENT

(Patent Document 1) Japanese Patent Laid-Open Publication No. 2004-128328

### SUMMARY

An aspect of the present disclosure may provide a multilayer ceramic electronic component capable of improving corner coverage of external electrodes to thereby improve reliability, and a board having the same mounted thereon.

According to an aspect of the present disclosure, a multilayer ceramic electronic component may include: a ceramic body including dielectric layers; an active layer configured to form capacitance by stacking a plurality of first and second internal electrodes alternately exposed to both end surfaces of the ceramic body with at least one of the dielectric layers interposed therebetween; upper and lower cover layers formed on and below the active layer; and first and second external electrodes formed on both end portions of the ceramic body, wherein, in a cross section of the ceramic body in a length-thickness direction, the first external electrode includes a first conductive layer formed at corner portions of the ceramic body, a first base electrode formed to cover the first conductive layer, and a first terminal electrode formed on the first base electrode, and the second external electrode includes a second conductive layer formed at corner portions of the ceramic body, a second base electrode formed to cover the second conductive layer, and a second terminal electrode formed on the second base electrode, the first and second conductive layers being positioned outside the active layer of the ceramic body.

Portions of the first and second base electrodes in which the first and second conductive layers are not formed on the end surfaces of the ceramic body may have a quadrangular shape.

The first and second base electrodes may contain at least one conductive metal selected from a group consisting of copper (Cu), nickel (Ni), silver (Ag), and silver-palladium (Ag—Pd), and glass.

The first and second conductive layers may contain a larger amount of the conductive metal and a smaller amount of the glass as compared to the first and second base electrodes.

The first and second conductive layers may contain a conductive resin.

The conductive resin may contain at least one conductive metal selected from a group consisting of copper (Cu), nickel (Ni), silver (Ag), and silver-palladium (Ag—Pd), and an epoxy resin.

According to another aspect of the present disclosure, a multilayer ceramic electronic component may include: a ceramic body including dielectric layers; an active layer configured to form capacitance by stacking a plurality of first and second internal electrodes alternately exposed to both end surfaces of the ceramic body with at least one of the dielectric layers interposed therebetween; upper and lower cover layers formed on and below the active layer; and first and second external electrodes formed on both end portions of the ceramic body, wherein, in a cross section of the ceramic body in a length-thickness direction, the first external electrode includes a first conductive layer formed at corner portions of the ceramic body, a first base electrode formed to cover the first conductive layer, and a first terminal electrode formed on the first base electrode, and the second external electrode includes a second conductive layer formed at corner portions of the ceramic body, a second base electrode formed to cover the second conductive layer, and a second terminal electrode formed on the second base electrode, the first and second base electrodes containing a conductive metal and glass, and the first and second conductive layers containing a larger amount of the conductive metal and a smaller amount of glass as compared to the first and second base electrodes.

Portions of the first and second base electrodes in which the first and second conductive layers are not formed on the end surfaces of the ceramic body may have a quadrangular shape.

The conductive metal may be at least one selected from a group consisting of copper (Cu), nickel (Ni), silver (Ag), and silver-palladium (Ag—Pd).

According to another aspect of the present disclosure, a board having a multilayer ceramic electronic component mounted thereon may include: a printed circuit board having first and second electrode pads formed thereon; and the multilayer ceramic electronic component as described above mounted on the printed circuit board.

Portions of the first and second base electrodes in which the first and second conductive layers are not formed on the end surfaces of the ceramic body may have a quadrangular shape.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic perspective view of a multilayer ceramic electronic component according to an exemplary embodiment of the present disclosure;

FIG. 2 is a cross-sectional view taken along line A-A′ of FIG. 1;

FIGS. 3A through 3F are schematic views of individual layers of an external electrode when viewed in a B direction of FIG. 1; and

FIG. 4 is a perspective view of a structure in which the multilayer ceramic electronic component of FIG. 1 is mounted on a printed circuit board.

### DETAILED DESCRIPTION

Exemplary embodiments of the present disclosure will now be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

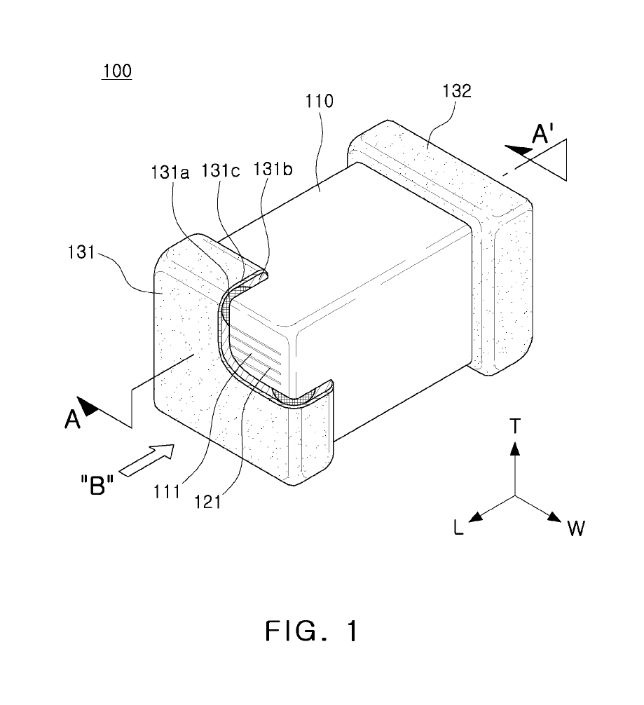

FIG. 1 is a schematic perspective view of a multilayer ceramic capacitor according to an exemplary embodiment of the present disclosure.

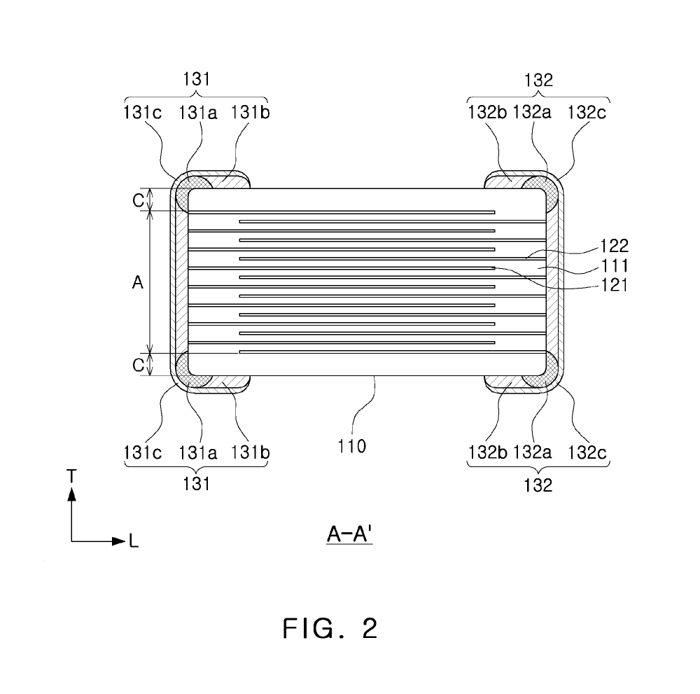

FIG. 2 is a cross-sectional view taken along line A-A′ of FIG. 1.

Referring to FIGS. 1 and 2, a multilayer ceramic electronic component according to an exemplary embodiment of the present disclosure may include: a ceramic body 110 including dielectric layers 111; an active layer A configured to form capacitance by stacking a plurality of first and second internal electrodes 121 and 122 alternately exposed to both end surfaces of the ceramic body 110 with at least one of the dielectric layers 111 interposed therebetween; upper and lower cover layers C formed on and below the active layer A; and first and second external electrodes 131 and 132 formed on both end portions of the ceramic body 110, wherein in a cross section of the ceramic body 110 in a length-thickness (L-T) direction, the first external electrode 131 includes a first conductive layer 131a formed at corner portions of the ceramic body 110, a first base electrode 131b formed to cover the first conductive layer 131a, and a first terminal electrode 131c formed on the first base electrode 131b, and the second external electrode 132 includes a second conductive layer 132a formed at corner portions of the ceramic body 110, a second base electrode 132b formed to cover the second conductive layer 132a, and a second terminal electrode 132c formed on the second base electrode 132b, the first and second conductive layers 131a and 132a being positioned outside the active layer A of the ceramic body 110.

Hereinafter, a multilayer ceramic electronic component according to an exemplary embodiment of the present disclosure will be described. Particularly, a multilayer ceramic capacitor 100 will be described as an example, but the present disclosure is not limited thereto.

In the multilayer ceramic capacitor 100 according to an exemplary embodiment of the present disclosure, a ‘length direction’ refers to an ‘L’ direction of FIG. 1, a ‘width direction’ refers to a ‘W’ direction of FIG. 1, and a ‘thickness direction’ refers to a ‘T’ direction of FIG. 1. Here, the ‘thickness direction’ may be the same direction as a direction in which dielectric layers are stacked, that is, a ‘stacked direction’.

In the exemplary embodiment of the present disclosure, a shape of the ceramic body 110 is not particularly limited, but may be hexahedral as shown in the accompanying drawings.

In the exemplary embodiment of the present disclosure, the ceramic body 110 may have first and second main surfaces opposing each other, the first and second side surfaces opposing each other, and the first and second end surfaces opposing each other, wherein the first and second main surfaces may be upper and lower surfaces of the ceramic body 110, respectively.

According to the exemplary embodiment of the present disclosure, a raw material forming the dielectric layers 111 is not particularly limited as long as sufficient capacitance may be obtained, but the material of the dielectric layers 111 may be, for example, a barium titanate (BaTiO₃) powder.

The material forming the dielectric layers 111 may further contain various ceramic additives, an organic solvent, a plasticizer, a binder, a dispersing agent, or the like, according to intended use of the capacitor, in addition to a powder such as a barium titanate (BaTiO₃) powder, or the like.

The ceramic body 110 may include the active layer A as apart contributing to forming capacitance of the capacitor and the upper and lower cover layers C formed on and below the active layer A, respectively, as upper and lower margin parts.

The active layer A may be formed by repeatedly stacking the plurality of first and second internal electrodes 121 and 122 with at least one of the dielectric layers 111 interposed therebetween.

The upper and lower cover layers C may have the same material and configuration as those of the dielectric layers 111 except that internal electrodes are not formed thereon.

The upper and lower cover layers C may be formed by stacking a single dielectric layer or at least two dielectric layers on upper and lower surfaces of the active layer A in a vertical direction, respectively, and generally serve to prevent the internal electrodes from being damaged by physical or chemical stress.

A material forming the first and second internal electrodes 121 and 122 is not particularly limited, but may be a conductive paste made of at least one of, for example, silver (Ag), lead (Pb), platinum (Pt), nickel (Ni), and copper (Cu).

The multilayer ceramic capacitor according to the exemplary embodiment of the present disclosure may include the first and second external electrode 131 and 132 formed on both end portions of the ceramic body 110 and electrically connected to the first and second internal electrodes 121 and 122, respectively.

The first and second external electrodes 131 and 132 may be electrically connected to the first and second internal electrodes 121 and 122 to form capacitance.

In the cross section of the ceramic body 110 in the length-thickness (L-T) direction, the first external electrode 131 may include the first conductive layer 131a formed at the corner portions of the ceramic body 110, the first base electrode 131b formed to cover the first conductive layer 131a, and the first terminal electrode 131c formed on the first base electrode 131b.

Further, in the cross section of the ceramic body 110 in the length-thickness (L-T) direction, the second external electrode 132 may include the second conductive layer 132a formed at the corner portions of the ceramic body 110, the second base electrode 132b formed to cover the second conductive layer 132a, and the second terminal electrode 132c formed on the second base electrode 132b.

Meanwhile, the first and second conductive layers 131a and 132a may be positioned outside the active layer A of the ceramic body 110.

Hereinafter, a structure of the first and second external electrodes 131 and 132 will be described in detail.

The first and second conductive layers 131a and 132a may be disposed at the corner portions of the ceramic body 110, respectively, thereby protecting the internal electrodes.

In general, as a multilayer ceramic electronic component is miniaturized and has high capacitance, a design for securing a target capacitance by increasing the number of stacked internal electrodes and decreasing thicknesses of upper and lower cover layers has been usually applied.

Therefore, the internal electrodes are formed up to the vicinity of the corner portions of the ceramic body where the thicknesses of the external electrodes are decreased at the time of forming the external electrodes, such that the internal electrodes may be easily exposed to physical or chemical impacts.

Particularly, as the overall thicknesses of the external electrodes of the multilayer ceramic electronic component are decreased, the thicknesses of the external electrodes in the vicinity of the corner portions of the ceramic body are further decreased, whereby corner coverage may deteriorate and a plating solution may infiltrate thereinto.

Further, in the case of external electrodes used in a high capacitance type electronic component, in order to decrease thermal impact at the time of sintering the external electrodes, a material capable of being sintered at a relatively low temperature is used. Particularly, in the case of glass softened at low temperatures, it may have relatively weak acid resistance at the time of plating. Due to these features, in the case in which a plating layer is formed in outer portions of the external electrodes, the plating solution may easily infiltrate, a leading cause of deteriorations in product quality due to deteriorations in moisture resistance reliability.

According to the exemplary embodiment of the present disclosure, the first and second conductive layers 131a and 132a are formed at the corner portions of the ceramic body 110, thereby preventing deteriorations in moisture resistance reliability due to the infiltration of the plating solution, without increasing the thicknesses of the first and second external electrodes 131 and 132.

Particularly, the first and second conductive layers 131a and 132a are formed to be positioned outside the active layer A of the ceramic body 110, whereby reliability may be improved without increasing the thicknesses of the first and second external electrodes 131 and 132.

In general, in order to solve deteriorations in moisture resistance reliability due to a reduction in thicknesses of external electrodes formed at corner portions of a ceramic body, a method of performing double application of an external electrode paste has been used. However, the overall thicknesses of the external electrodes may be increased, whereby it may be difficult to miniaturize a product.

However, according to the exemplary embodiment of the present disclosure, the first and second conductive layers 131a and 132a may be formed at the corner portions of the ceramic body 110 but positioned outside the active layer A of the ceramic body 110, such that the overall thicknesses of the external electrodes are not increased but are maintained.

That is, the first and second conductive layers 131a and 132a are formed at the corner portions of the ceramic body so that one end portions thereof are disposed in a region corresponding to the outside of the active layer A, that is, a region corresponding to the cover layer C, such that the overall thicknesses of the external electrodes are not increased.

The first and second conductive layers 131a and 132a may contain a larger amount of a conductive metal and a smaller amount of glass as compared to the first and second base electrodes 131b and 132b.

That is, the first and second conductive layers 131a and 132a may contain at least one conductive metal selected from a group consisting of copper (Cu), nickel (Ni), silver (Ag), and silver-palladium (Ag—Pd), and glass, similarly to the first and second base electrodes 131b and 132b, but the contents of the conductive metal and the glass in the first and second conductive layers 131a and 132a may be different from those in the first and second base electrodes 131b and 132b.

Since the first and second conductive layers 131a and 132a contain a larger amount of the conductive metal and a smaller amount of the glass as compared to the first and second base electrodes 131b and 132b, the multilayer ceramic capacitor may achieve excellent reliability by improving the corner coverage of the external electrodes to thereby prevent deteriorations in moisture resistance properties due to the infiltration of the plating solution.

That is, since the first and second conductive layers 131a and 132a are formed in order to solve the infiltration of the plating solution due to the reduced thicknesses of the first and second base electrodes 131b and 132b formed at the corner portions of the ceramic body 110, the first and second conductive layers 131a and 132a may contain a larger amount of conductive metal as compared to the first and second base electrodes 131b and 132b in order to further improve the effect of preventing the infiltration of the plating solution.

Similarly, in order to further improve the effect of preventing the infiltration of the plating solution, the first and second conductive layers 131a and 132a may contain a smaller content of glass as compared to the first and second base electrodes 131b and 132b.

According to another exemplary embodiment of the present disclosure, the first and second conductive layers 131a and 132a may contain a conductive resin, but are not necessarily limited thereto.

The conductive resin is not particularly limited, but may contain, for example, at least one conductive metal selected from a group consisting of copper (Cu), nickel (Ni), silver (Ag), and silver-palladium (Ag—Pd), and an epoxy resin.

According to the exemplary embodiment of the present disclosure, the first external electrode 131 may include the first base electrode 131b formed to cover the first conductive layer 131a, and the second external electrode 132 may include the second base electrode 132b formed to cover the second conductive layer 132a.

In order to form capacitance, the first and second external electrodes 131 and 132 may be formed on both end surfaces of the ceramic body 110, and the first and second base electrodes 131b and 132b included in the first and second external electrodes 131 and 132 may be electrically connected to the first and second internal electrodes 121 and 122, respectively.

The first and second base electrodes 131b and 132b may be formed of the same conductive material as that of the first and second internal electrodes 121 and 122 but are not limited thereto. For example, the first and second base electrodes 131b and 132b may contain at least one conductive metal selected from a group consisting of copper (Cu), nickel (Ni), silver (Ag), and silver-palladium (Ag—Pd).

The first and second base electrodes 131b and 132b may be formed by applying a conductive paste prepared by adding glass frits to the conductive metal powder and then sintering the applied conductive paste.

Meanwhile, the first external electrode 131 may include the first terminal electrode 131c formed on the first base electrode 131b, and the second external electrode 132 may include the second terminal electrode 132c formed on the second base electrode 132b.

The first and second terminal electrodes 131c and 132c may be formed by plating. Particularly, the first and second terminal electrodes 131c and 132c may be a nickel/tin plating layer, but are not limited thereto.

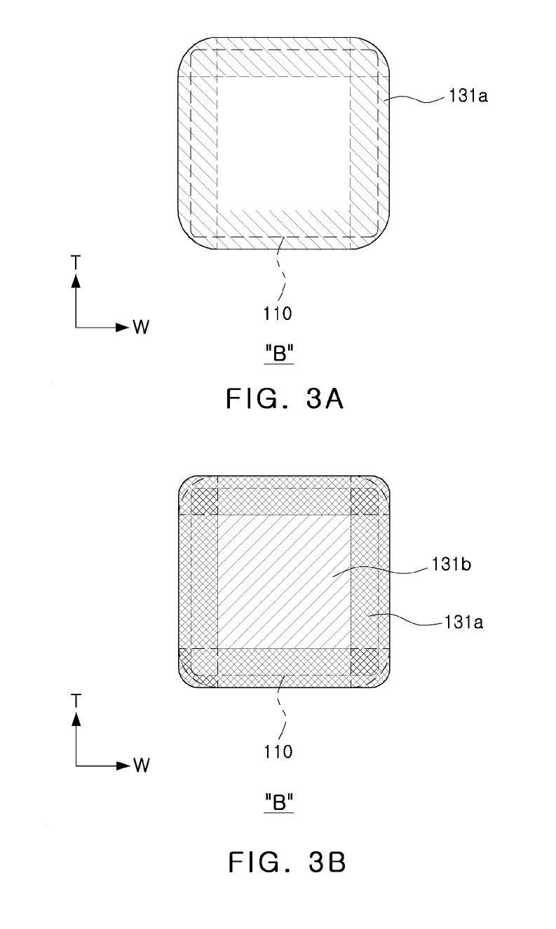

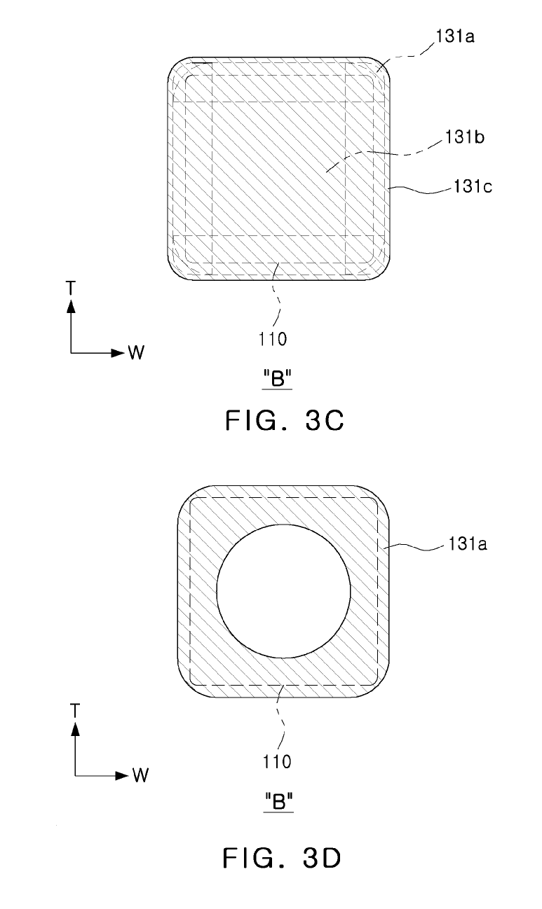

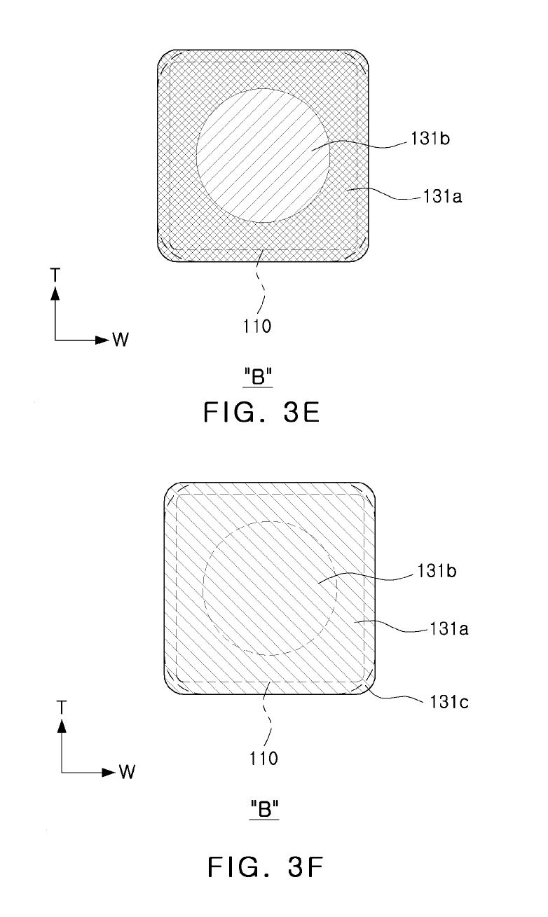

FIGS. 3A through 3F are schematic views of individual layers of an external electrode when viewed in a B direction of FIG. 1.

Referring to FIGS. 3A through 3C, a portion of the first base electrode 131b, in which the first conductive layers 131a are not formed, on an end surface of the ceramic body 110 may have a quadrangular shape.

According to this exemplary embodiment of the present disclosure, the first conductive layers 131a may be formed in thin portions of the first base electrode 131b formed on the end surface of the ceramic body 110, which are vulnerable to a plating solution. That is, the first conductive layers 131a maybe formed at corner portions of the end surface of the ceramic body 110.

Here, the first conductive layers 131a may be formed by a printing method and may be formed on the upper and lower cover layers, the margin parts of the ceramic body in the width direction, except for the active layer A, such that the portion of the first base electrode 131b in which the first conductive layers 131a are not formed may have a quadrangular shape.

In the case in which the portion of the first base electrode 131b in which the first conductive layers 131a are not formed has the quadrangular shape as described above, the effect of preventing the infiltration of the plating solution may be excellent.

Meanwhile, referring to FIGS. 3D through 3F, in a multilayer ceramic capacitor according to another exemplary embodiment of the present disclosure, a portion of the first base electrode 131b in which the first conductive layers 131a are not formed on an end surface of the ceramic body 110 may have a circular shape.

The first conductive layers 131a may be formed by a printed method and may be formed on the upper and lower cover layers, the margin parts of the ceramic body in the width direction, except for the active layer A, such that the portions of the first base electrode 131b in which the first conductive layers 131a are not formed may have the circular shape.

In the case in which the portion of the first base electrode 131b in which the first conductive layers 131a are not formed has the circular shape as described above, the effect of preventing the infiltration of the plating solution may be excellent.

In the case in which the portion of the first base electrode 131b in which the first conductive layers 131a are not formed has the quadrangular shape as described above, a corner coverage area of the external electrode may be uniform as compared to the circular shape, such that the effect of preventing the infiltration of the plating solution may be further improved.

Since the second external electrode 132 has the same configuration as that of the first external electrode 131, a detailed description thereof will be omitted.

A multilayer ceramic electronic component according to another exemplary embodiment of the present disclosure may include: a ceramic body 110 including dielectric layers 111; an active layer A configured to form capacitance by stacking a plurality of first and second internal electrodes 121 and 122 alternately exposed to both end surfaces of the ceramic body 110 with at least one of the dielectric layers 111 interposed therebetween; upper and lower cover layers C formed on and below the active layer A; and first and second external electrodes 131 and 132 formed on both end portions of the ceramic body 110, wherein in a cross section of the ceramic body 110 in a length-thickness (L-T) direction, the first external electrode 131 includes a first conductive layer 131a formed at corner portions of the ceramic body 110, a first base electrode 131b formed to cover the first conductive layer 131a, and a first terminal electrode 131c formed on the first base electrode 131b, and the second external electrode 132 includes a second conductive layer 132a formed at corner portions of the ceramic body 110, a second base electrode 132b formed to cover the second conductive layer 132a, and a second terminal electrode 132c formed on the second base electrode 132b, the first and second base electrodes 131b and 132b containing a conductive metal and glass, and the first and second conductive layers 131a and 132a containing a larger amount of the conductive metal and a smaller amount of glass as compared to the first and second base electrodes 131b and 132b.

Portions of the first and second base electrodes 131b and 132b, in which the first and second conductive layers 131a and 132a are not formed, on the end surfaces of the ceramic body 110 may have a quadrangular shape.

The conductive metal may be at least one selected from a group consisting of copper (Cu), nickel (Ni), silver (Ag), and silver-palladium (Ag—Pd).

Features of the multilayer ceramic electronic component according to this exemplary embodiment of the present disclosure, the same as those of the multilayer ceramic electronic component according to the previous exemplary embodiment of the present disclosure, will be omitted.

Hereinafter, a method of manufacturing a multilayer ceramic electronic component according to another embodiment of the present disclosure will be described in detail. Particularly, a multilayer ceramic capacitor will be described as an example, but the present disclosure is not limited thereto.

First, a ceramic body 110, including dielectric layers 111 and first and second internal electrodes 121 and 122 disposed to face each other with at least one of the dielectric layers 111 interposed therebetween, may be prepared.

The dielectric layers 111 may be formed of ceramic green sheets having a thickness of several μm by applying slurry prepared by mixing a powder such as a barium titanate (BaTiO₃) powder, or the like, with a ceramic additive, an organic solvent, a plasticizer, a binder, and a dispersing agent to carrier films using a basket mill and drying the same.

Then, internal electrode layers may be formed of a conductive paste by dispensing the conductive paste on the green sheets while moving a squeegee in a single direction.

Here, the conductive paste may be formed of at least one of a noble metal material such as silver (Ag), lead (Pb), platinum (Pt), or the like, nickel (Ni), and copper (Cu) and a mixture of at least two materials thereof.

After the internal electrode layers are formed as described above, a multilayer body may be formed by separating the green sheets from the carrier films and then stacking the plurality of green sheets to be overlapped with each other.

Then, the ceramic body may be manufactured by compressing the green sheet multilayer body at high temperatures and high pressure and then cutting the compressed green sheet multilayer body to have a predetermined size.

Next, first and second external electrodes 131 and 132 may be formed on end portions of the ceramic body 110 to be electrically connected to the first and second internal electrodes 121 and 122.

In a process for forming the first and second external electrodes 131 and 132, first, a conductive paste containing a conductive metal and glass may be applied to corner portions of the ceramic body, thereby forming first and second conductive layers.

The conductive metal may be at least one selected from a group consisting of copper (Cu), nickel (Ni), silver (Ag), and silver-palladium (Ag—Pd).

The conductive paste forming the first and second conductive layers may contain a larger amount of the conductive metal and a smaller amount of the glass as compared to a conductive paste forming first and second base electrodes to be described below.

Next, a conductive paste for external electrodes containing the conductive metal and the glass may be applied to both end portions of the ceramic body, thereby forming the first and second base electrodes.

The first and second base electrodes may be formed to cover the first and second conductive layers.

The contents of the conductive metal and the glass contained in the first and second base electrodes and the first and second conductive layers are not particularly limited. In the case in which a ratio of the conductive metal to the glass contained in the first and second base electrodes is 6:4, a ratio of the conductive metal to the glass contained in the first and second conductive layers may be 8:2.

Thereafter, first and second terminal electrodes may be formed on the first and second base electrodes, respectively, by plating.

The first and second terminal electrodes are not particularly limited as long as they are plating layers, and may be formed of, for example, a nickel/tin plating layer.

Finally, a multilayer ceramic capacitor may be manufactured by sintering the ceramic body.

Other details of the method of manufacturing a multilayer ceramic capacitor except for the above-mentioned features thereof are the same as those in a general method of manufacturing a multilayer ceramic capacitor.

As a result, according to the exemplary embodiment of the present disclosure, the first external electrode includes the first conductive layers formed at the corner portions of the ceramic body and the first base electrode formed to cover the first conductive layer and the second external electrode includes the second conductive layers formed at the corner portions of the ceramic body, the second base electrode formed to cover the second conductive layer, whereby the multilayer ceramic electronic component may achieve excellent reliability.

That is, according to the exemplary embodiment of the present disclosure, the chip sealing properties may be improved, without an increase in the thicknesses of the external electrodes, whereby the multilayer ceramic electronic component may be miniaturized and achieve excellent reliability and high capacitance.

### Board Having Multilayer Ceramic Electronic Component Mounted Thereon

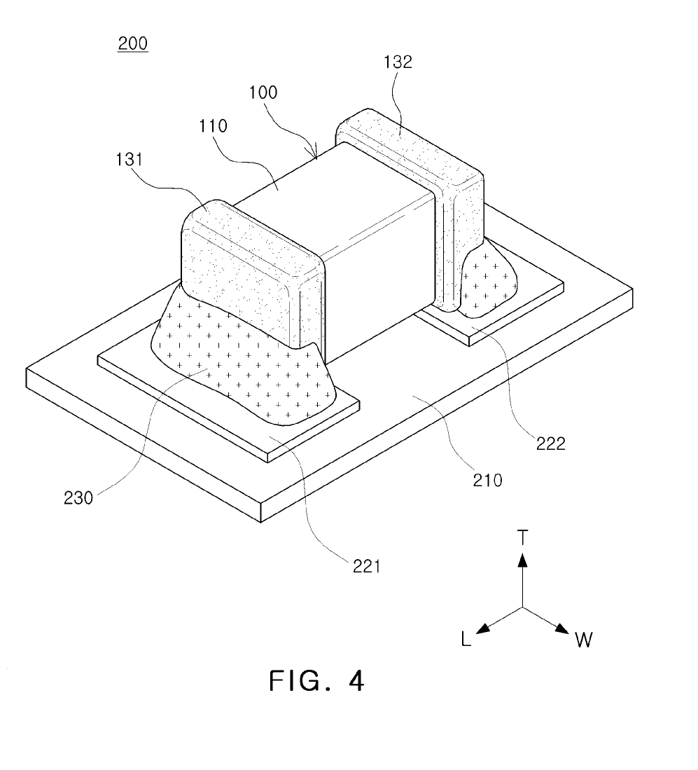

FIG. 4 is a perspective view of a structure in which the multilayer ceramic capacitor of FIG. 1 is mounted on a printed circuit board.

Referring to FIG. 4, a board 200 having a multilayer ceramic capacitor mounted thereon according to this exemplary embodiment of the present disclosure may include a printed circuit board 210 on which the multilayer ceramic capacitor 100 is horizontally mounted and first and second electrode pads 221 and 222 formed on the printed circuit board 210 to be spaced apart from each other.

In this case, the multilayer ceramic capacitor 100 may be electrically connected to the printed circuit board 210 by solders 230 in a state in which the lower cover layer thereof is disposed downwardly and the first and second external electrodes 131 and 132 are positioned to contact the first and second electrode pads 221 and 222, respectively.

Portions of the first and second base electrodes 131b and 132b in which the first and second conductive layers 131a and 132a are not formed on the end surface of the ceramic body 110 may have a quadrangular shape.

As set forth above, according to exemplary embodiments of the present disclosure, in the first and second external electrodes, the conductive layers are additionally formed at the corner portions of the ceramic body, whereby the corner coverage of the external electrodes maybe improved, and the multilayer ceramic electronic component may have improved reliability.

While exemplary embodiments have been shown and described above, it will be apparent to those skilled in the art that modifications and variations could be made without departing from the spirit and scope of the present disclosure as defined by the appended claims.

What is claimed is:

1. A multilayer ceramic electronic component, comprising:
a ceramic body including dielectric layers;
an active layer including a plurality of first and second internal electrodes alternately exposed to end surfaces of the ceramic body, at least one of the dielectric layers interposed between the first and second internal electrodes;
upper and lower cover layers formed on and below the active layer; and
first and second external electrodes formed on both end portions of the ceramic body,
wherein, in a cross section of the ceramic body in a length-thickness direction, the first external electrode includes a first conductive layer formed at corner portions of the ceramic body, a first base electrode formed to cover the first conductive layer, and a first terminal electrode formed on the first base electrode, and the second external electrode includes a second conductive layer formed at corner portions of the ceramic body, a second base electrode formed to cover the second conductive layer, and a second terminal electrode formed on the second base electrode,
the first and second conductive layers are positioned outside the active layer of the ceramic body.

2. The multilayer ceramic electronic component of claim 1, wherein portions of the first and second base electrodes in which the first and second conductive layers are not formed on the end surfaces of the ceramic body have a quadrangular shape.

3. The multilayer ceramic electronic component of claim 1, wherein the first and second base electrodes contain at least one conductive metal selected from a group consisting of copper (Cu), nickel (Ni), silver (Ag), and silver-palladium (Ag—Pd), and glass.

4. The multilayer ceramic electronic component of claim 3, wherein the first and second conductive layers contain a larger amount of the conductive metal and a smaller amount of the glass as compared to the first and second base electrodes.

5. The multilayer ceramic electronic component of claim 1, wherein the first and second conductive layers contain a conductive resin.

6. The multilayer ceramic electronic component of claim 5, wherein the conductive resin contains at least one conductive metal selected from a group consisting of copper (Cu), nickel (Ni), silver (Ag), and silver-palladium (Ag—Pd), and an epoxy resin.

7. A multilayer ceramic electronic component, comprising:
a ceramic body including dielectric layers;
an active layer configured to form capacitance by stacking a plurality of first and second internal electrodes alternately exposed to both end surfaces of the ceramic body with at least one of the dielectric layers interposed therebetween;
upper and lower cover layers formed on and below the active layer; and
first and second external electrodes formed on both end portions of the ceramic body,
wherein, in a cross section of the ceramic body in a length-thickness direction, the first external electrode includes a first conductive layer formed at corner portions of the ceramic body, a first base electrode formed to cover the first conductive layer, and a first terminal electrode formed on the first base electrode, and the second external electrode includes a second conductive layer formed at corner portions of the ceramic body, a second base electrode formed to cover the second conductive layer, and a second terminal electrode formed on the second base electrode,
the first and second base electrodes contain a conductive metal and glass, and
the first and second conductive layers contain a larger amount of the conductive metal and a smaller amount of the glass as compared to the first and second base electrodes.

8. The multilayer ceramic electronic component of claim 7, wherein portions of the first and second base electrodes in which the first and second conductive layers are not formed on the end surfaces of the ceramic body have a quadrangular shape.

9. The multilayer ceramic electronic component of claim 7, wherein the conductive metal is at least one selected from a group consisting of copper (Cu), nickel (Ni), silver(Ag), and silver-palladium (Ag—Pd).

10. A board having a multilayer ceramic electronic component mounted thereon, the board comprising:
a printed circuit board having first and second electrode pads formed thereon; and
the multilayer ceramic electronic component of claim 1 mounted on the printed circuit board.

11. The board of claim 10, wherein portions of the first and second base electrodes in which the first and second conductive layers are not formed on the end surfaces of the ceramic body have a quadrangular shape.

12. A board having a multilayer ceramic electronic component mounted thereon, the board comprising:
a printed circuit board having first and second electrode pads formed thereon; and
the multilayer ceramic electronic component of claim 7 mounted on the printed circuit board.

13. The board of claim 12, wherein portions of the first and second base electrodes in which the first and second conductive layers are not formed on the end surfaces of the ceramic body have a quadrangular shape.
